(19) United States
(12) Patent Application Publication
(10) Pub. No.: US 2026/0215019 A1
(43) Pub. Date: Jul. 23, 2026

(54) MINIATURIZED IMAGE SENSOR PACKAGING STRUCTURE AND IMAGE SENSING MODULE

(71) Applicant: Medimaging Integrated Solution, Inc., Hsinchu (TW)

(72) Inventors: SHANGYI WU, Hsinchu (TW); HSIN-HSIEN HSIEH, Hsinchu (TW); CHIH LUNG HSU, Hsinchu (TW)

(21) Appl. No.: 19/319,292

(22) Filed: Sep. 4, 2025

(30) Foreign Application Priority Data
Jan. 23, 2025 (TW) 114201044

(51) Int. Cl. H10F 39/00; H10F 39/18; H10F 39/95

(52) U.S. Cl. CPC H10F 39/811; H10F 39/182; H10F 39/95

(57) ABSTRACT

A miniaturized image sensor packaging structure includes a carrier substrate, image sensors and a resin layer. The front side of the carrier substrate is divided into a plurality of package areas in an array configuration. The package area is equipped with a plurality of solder pad-inner circuit sets arranged in array. Through holes are formed at four corners of the package area. The image sensor is mounted on the package area with its four corners above the through holes. The resin layer is formed between the image sensor and the carrier substrate. After the package area is cut, the carrier substrate, the image sensor, the resin layer and a lens module jointly form a single image sensing module. Since the four corners of the image sensing module are protruded above the carrier substrate, the diagonal dimension of the image sensing module will be equal to the diagonal dimension of the image sensor or lens module.

### BACKGROUND OF THE INVENTION

### 1. Field of the Invention

The present invention relates to an image sensing module, particularly to a miniaturized image sensor packaging structure and an image sensing module.

### 2. Description of the Prior Art

The current image sensing module is generally formed by the following processes: the image capturing lens module having been assembled to the barrel, which is called the barrel-type lens module thereinafter, is aligned and assembled to the image sensor that has been bonded to the carrier board (PCB or FPC) through an automatic alignment device; a multi-axis adjustment machine is used to perform adjusting the image sensor and obtain the optimized image; an adhesive is dispensed to fix the relative position of the image capturing lens module and the image sensor and obtain a complete image sensing module having an image capturing lens module.

Another technology of fabricating optical image sensing modules adopts a wafer-level technology: the completed wafer-level-package image sensors and the corresponding wafer-level lenses are aligned and stacked together adhesively layer by layer; the finished array is cut to obtain the required image sensing modules; a black or dark-color material is coated on the peripheral of the image sensing module to shield light lest stray light enter the lens and affect the image quality.

In the abovementioned conventional technology where the image sensor and the conventional circular barrel-type lens module are assembled together, the finished image sensing module would have a larger outer diameter. Thus, the endoscope using the image sensing module would have too larger a? front end. Therefore, the image sensing module is hard to be applied to a smaller-size endoscope. In the abovementioned conventional technology where the image sensors and the lenses are fabricated in a wafer-level package method, the small size thereof increases fabrication difficulty, resulting in lower yield rate and high price. However, the wafer-level package process is unlikely to automatically align the lenses and the image sensors. Each wafer-level lens can only be aligned and adhesively assembled through alignment marks. In other words, the wafer-level package process cannot adjust the position according to image quality and is unlikely to control the imaging quality of each image sensor on the wafer. Thus, the yield thereof is degraded. Besides, the wafer-level package process is unlikely screen out the damaged image sensors during fabrication. Though some damaged image sensors have been known, the lens package process cannot be interrupted but must be completed thoroughly. Then, the cost increases. Besides, the optics specifications (such as the field of view and the depth of field) of the abovementioned technology are unlikely to adjust any more once the specifications have been decided. Therefore, they cannot be adjusted to satisfy requirements of different endoscopes by the users. If the specifications are intended to be changed, much money would be spent in redesigning the forming molds of the wafer-level lenses. Hence, the wafer-level lens is more expensive than the barrel-type lens in such a situation. Therefore, the wafer-level lens is harder to fabricate, lower in yield, and higher in cost.

### SUMMARY OF THE INVENTION

Considering the abovementioned problems, one objective of the present invention is to provide a miniaturized image sensor packaging structure and an image sensing module. In the miniaturized image sensor packaging structure of the present invention, through holes are respectively formed in the portions of the carrier substrate, which are corresponding to four corners of the image sensor, whereby the carrier substrate will not influence the final size of the image sensing module after packaging and cutting, and whereby the image sensing module may achieve the minimum diagonal dimension, wherefore the present invention can realize miniaturization of products.

In order to achieve the abovementioned objective, the present invention provides a miniaturized image sensor packaging structure, which comprises a carrier substrate, a plurality of image sensors, and a resin layer. The carrier substrate has a front surface and a back surface. The front surface is divided into a plurality of package areas, which are arranged in array. Each package area has a plurality of solder pad-inner circuit sets, which are arranged in array and inner electrical circuits connect the pads on front surface and back surface with each other Through holes are respectively formed on four corners of the package area. The image sensors are respectively disposed on the package areas. Four corners of the image sensor are respectively disposed above the through holes at four corners of the package area and in a protruded state. The resin layer is formed between the image sensors and the carrier substrate.

The present invention also provides an image sensing module, which comprises a carrier substrate, an image sensor, a resin layer, and a lens module. The carrier substrate has a front surface and a back surface. The front surface has a plurality of solder pad-inner circuit sets, and the inner electrical circuits connect the pads on front surface and back surface with each other. Through holes are respectively formed on four corners of the package area. The image sensors are respectively disposed on the package areas. Four corners of the image sensor are respectively disposed above the through holes at four corners of the package area and in a protruded state. The resin layer is formed between the image sensor and the carrier substrate. The lens module is disposed on the image sensor.

In some embodiments of the present invention, each solder pad-inner circuit set has at least one connection solder pad, which is formed on the front surface of the carrier substrate. The image sensor is disposed above the front surface of the carrier substrate. The bottom of each image sensor has a plurality of electrodes, which are electrically connected with the connection solder pads on the front surface of the carrier substrate.

In some embodiments of the present invention, each solder pad-inner circuit set also has at least one electrode solder pad, which is formed on the back surface of the carrier substrate. The electrode solder pads are to be electrically connected with required electronic elements.

In some embodiments of the present invention, the abovementioned miniaturized image sensor packaging structure further comprises a plurality of lens modules. The lens modules are respectively disposed on the image sensors. After the package areas are separated by cutting, the carrier substrate, the image sensor, the resin layer, and the lens module jointly form a single image sensing module.

In some embodiments of the present invention, the diagonal dimension of the image sensing module is equal to the diagonal dimension of the image sensor or the dimension of the lens module.

In some embodiments of the present invention, a combination of the image sensor and the lens module is in form of an image sensor containing a lens module.

In some embodiments of the present invention, the carrier substrate may be but is not limited to be a ceramic substrate, a printed circuit board (PCB) substrate, or a flexible printed circuit (FPC) substrate.

In comparison with the conventional technology, the present invention has the following advantages:
1. In the miniaturized image sensor packaging structure and the image sensing module according to the embodiments of the present invention, the portions of the carrier substrate, which are corresponding to four corners of the image sensor, are perforated, whereby the diagonal dimension of the post-package and cutting carrier substrate is equal to or smaller than the diagonal dimension of the image sensing module; the maximum diagonal dimension of the image sensing module is equal to the diagonal dimension of the image sensor or the diagonal dimension the lens module; using the abovementioned carrier substrate in packaging will not influence the final dimension of the image sensing module but may further decrease the diameter of the front end of the endoscope where the image sensing module is applied.
2. In the miniaturized image sensor packaging structure and the image sensing module according to the embodiments of the present invention, both the image sensor and the lens module can be tested to verify the quality thereof before assembling, whereby the conventional problem that the wafer-level packaging technology cannot screen out unqualified and failed image sensors but have to assemble the unqualified and failed image sensor and the lens module together. Then, the present invention increases the yield rate of assembling the image sensor and the lens module.
3. In the miniaturized image sensor packaging structure and the image sensing module according to the embodiments of the present invention, the image sensors and the lens modules are arranged on the carrier substrate in array and then joined together and packaged, whereby the present invention can realize a wafer-level-like production mode, achieve mass production, and realize miniaturization of image sensing modules and endoscopes.
4. In the miniaturized image sensor packaging structure and the image sensing module according to the embodiments of the present invention, the space on the back of the carrier substrate may be designed to accommodate circuits and corresponding electronic elements. Thereby, the space on the back surface of the carrier substrate may be fully utilized. Thus, the final size of the image sensing module may be decreased; and the functions of the image sensing module may be increased.

The objective, technologies, features and advantages of the present invention will become apparent from the following description in conjunction with the accompanying drawings wherein certain embodiments of the present invention are set forth by way of illustration and example.

### BRIEF DESCRIPTION OF THE DRAWINGS

The foregoing conceptions and their accompanying advantages of this invention will become more readily appreciated after being better understood by referring to the following detailed description, in conjunction with the accompanying drawings, wherein

FIG. 1 is a diagram schematically showing a carrier substrate of a miniaturized image sensor packaging structure according to the embodiments of the present invention;

FIGS. 2A and 2B are respectively a front view and a rear view of the package area in FIG. 1;

FIG. 3 is a diagram schematically showing that image sensors of a miniaturized image sensor packaging structure are disposed on a carrier substrate according to the embodiments of the present invention;

FIGS. 4A and 4B are respectively a front view and a side view of the package area in FIG. 3;

FIG. 5 is a diagram schematically showing that a resin layer is formed between the image sensors and the carrier substrate of a miniaturized image sensor packaging structure according to the embodiments of the present invention;

FIGS. 6A and 6B are respectively a side view and a front view of the package area in FIG. 5;

FIG. 7 is a diagram schematically showing that a lens module is disposed on an image sensor in a miniaturized image sensor packaging structure according to the embodiments of the present invention;

FIG. 8 is a diagram schematically showing that the image sensing packaging modules of a miniaturized image sensor packaging structure are arranged in array according to the embodiments of the present invention;

FIGS. 9A and 9B are respectively a front view and a side view of the package area in FIG. 8;

FIG. 10 is a diagram schematically showing that electronic elements are disposed on the back surface of the carrier substrate of a miniaturized image sensor packaging structure according to the embodiments of the present invention;

FIGS. 11A and 11B are respectively a rear view and a side view of the package area in FIG. 10;

FIGS. 12A and 12B are respectively a front view and an appearance of the image sensing module obtained via cutting the miniaturized image sensor packaging structure according to the embodiments of the present invention;

FIG. 13 is a diagram schematically showing that a protective resin material is used to secure the image sensing module obtained according to the embodiments of the present invention.

### DESCRIPTION OF THE PREFERRED EMBODIMENTS

The embodiments of the present invention will be further demonstrated in details hereinafter in cooperation with the corresponding drawings. In the drawings and the specification, the same numerals represent the same or the like elements as much as possible. For simplicity and convenient labelling, the shapes and thicknesses of the elements may be exaggerated in the drawings. It is easily understood: the elements belonging to the conventional technologies and well known by the persons skilled in the art may be not particularly depicted in the drawings or described in the specification. Various modifications and variations made by the persons skilled in the art according to the contents of the present invention are to be included by the scope of the present invention.

The fundamental thought of the present invention is to provide a miniaturized image sensor packaging structure and an image sensing module, wherein four corners of the carrier substrate where the image sensor is disposed are perforated, whereby to obtain an image sensing module having a minimum diagonal dimension after packaging and cutting, wherefore the present invention can minimize the size of the product where the image sensing module is applied.

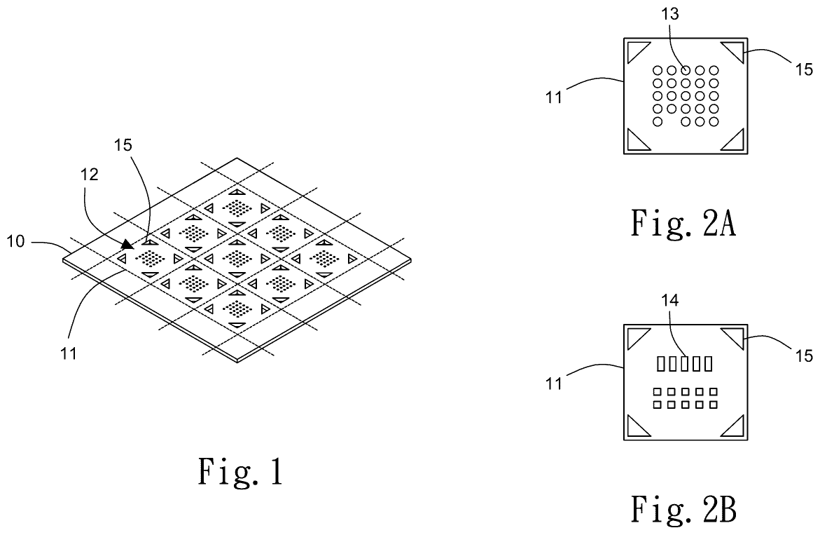

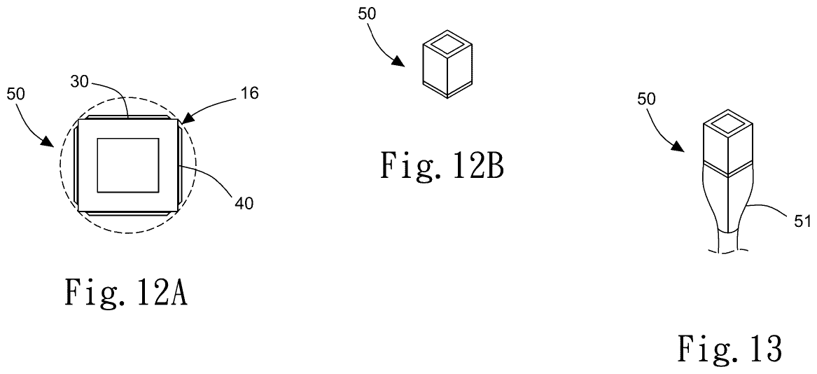

Refer to FIGS. 1-11B for the fabrication process of a miniaturized image sensor packaging structure 100 according to embodiments of the present invention. Also refer to FIGS. 12A-13 for the method of applying the miniaturized image sensor packaging structure 100 to fabricate single image sensing modules 50 according to embodiments of the present invention.

Refer to FIG. 1, FIG. 2A, and FIG. 2B. Firstly, provide a carrier substrate 10. In some embodiments of the present invention, the carrier substrate 10 may be a ceramic substrate, a printed circuit board (PCB), or a flexible printed circuit (FPC) board. The carrier substrate 10 has a front surface and a back surface. The front surface of the carrier substrate 10 is divided into a plurality of package areas 11, which are arranged in array. The package area 11 is used to install the image sensor. Each package area 11 has a plurality of solder pad-inner circuit sets 12. Each s solder pad-inner circuit set 12 includes at least one connection solder pad 13 and at least one electrode solder pad 14. The connection solder pads 13 are disposed on the front surface (as shown in FIG. 2A) and connected with the image sensor. The electrode solder pads 14 are disposed on the back surface of the carrier substrate 10 (as shown in FIG. 2B) and used for image and electrical signals transmission and wire soldering. Through holes 15 are respectively formed on four corners of the package area 11. The shape of the through holes is not particularly limited as long as the areas of the through holes 15 allow the image sensor to be disposed over the package area 11 and let four corner sections of the image sensor be protruded. It should be noted: the protruded regions are not allowed to contact the electrodes on the bottom of the image sensor.

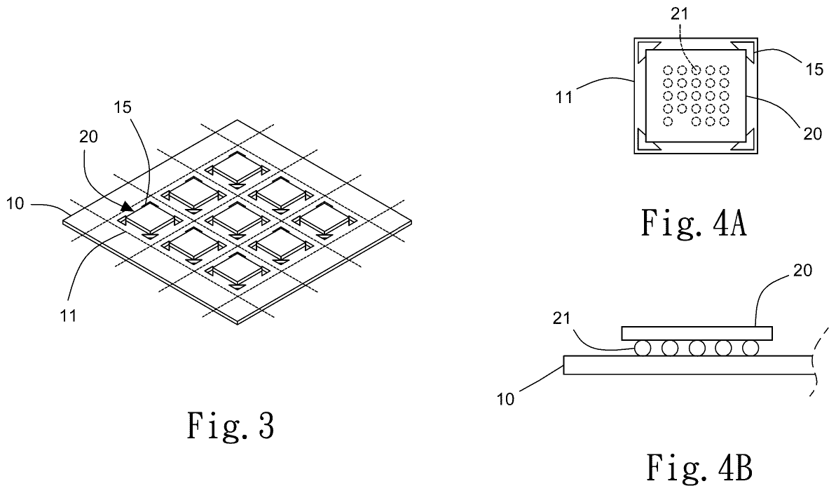

Refer to FIG. 3 and FIG. 4A, and FIG. 4B. An image sensor 20 is placed above the package area 11 of the front surface of the carrier substrate 10 for a high-temperature joining operation and a fixing operation. The electrodes 21 (Ball Grid Array (BGA) solder bumps herein) on the bottom of the image sensor 20 are electrically connected with the connection solder pads 13 of the carrier substrate 10. The four corners of the image sensor 20 are positioned above the through holes 15 to make the four corners of the image sensor 20 in a protruded state.

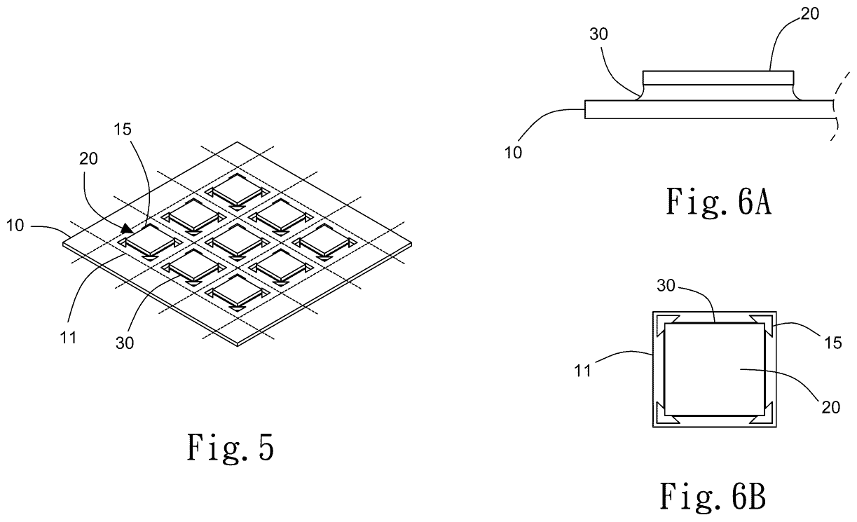

Refer to FIG. 5, FIG. 6A, and FIG. 6B. A resin material is filled onto the bottom of the image sensor 20 to form a resin layer 30 between the image sensor 20 and the carrier substrate 10, whereby to protect the joint points between the image sensor 20 and the carrier substrate 10.

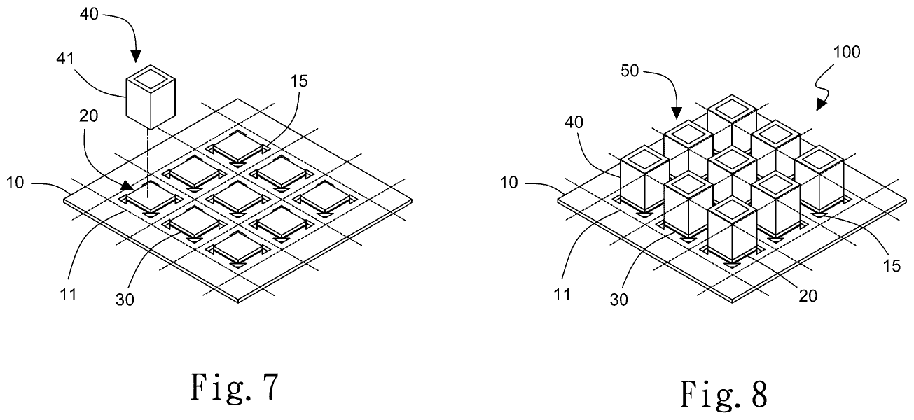

Refer to FIG. 7. A lens module 40 having a light-shield layer 41 is placed above the image sensor 20. After an alignment operation and a focusing operation, the image sensor 20 and the lens module 40 are fixed with a resin material. Alternatively, the combination of the image sensor 20 and the lens module 40 may be replaced by an image sensor containing a lens module. The image sensor containing a lens module may be directly placed on the carrier substrate 20, whereby the alignment operation and the focusing operation of the lens module 40, which are undertaken above the carrier substrate 10, can be omitted.

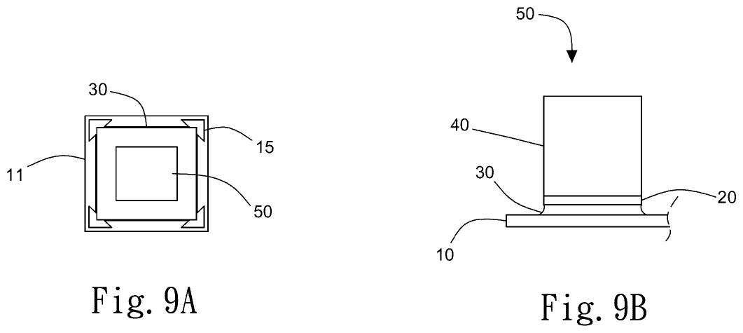

Refer to FIG. 8, FIG. 9A, and FIG. 9B. All the image sensors 20 and the lens modules 40 are fixed onto the package areas 11 one by one to form array-type image sensing modules 50.

It is explained additionally: the miniaturized image sensor packaging structure 100 of the present invention is formed by the carrier substrate 10, a plurality of image sensors 20, a resin layer 30, and a plurality of lens modules 40; the front surface of the carrier substrate 10 is divided into a plurality of package areas 11, which are arranged in array (as shown in FIG. 1); through holes 15 are respectively formed on four corners of the package area 11; the image sensor 20 is disposed above the package area 11, and four corners of the image sensor 20 are over the through holes 15; the resin layer 30 is filled into the space between the image sensor 20 and the carrier substrate 10; the lens module 40 is disposed on the image sensor 20; the carrier substrate 10, the image sensor 20, the resin layer 30 and the lens module 40 of each package area 40 jointly form a single image sensing module 50.

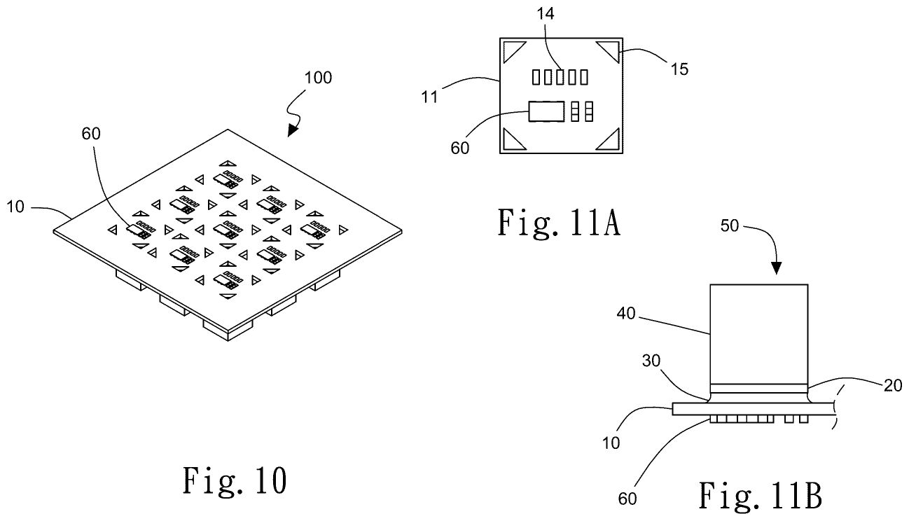

Refer to FIG. 10, FIG. 11A, and FIG. 11B. In one embodiment, according to the demand of practical application, a required electronic element 60 (such as a passive element) may be electrically connected with the electrode solder pads 14 on the back surface of the carrier substrate 10. Thereby, the space on the back surface of the carrier substrate 10 may be fully utilized. Thus, the space required by the electronic element 60 can be decreased; the size of the image sensing module 50 may be minimized; and the functions of the image sensing module 50 may be increased (such as the temperature sensing function).

Next, the carrier substrate 10 is cut to separate the package areas 11 to obtain a plurality of single image sensing modules 50, as shown in FIG. 12A and FIG. 12B. Each image sensing module 50 is formed by the carrier substrate 10, the image sensor 20, the resin layer 30 and the lens module 40 (as shown in FIG. 8). The through holes 15, which are respectively corresponding to four corners of the package area 11, will become notches 16 (as shown in FIG. 12A). The bottoms of four corners of the image sensor 20 are corresponding to the positions of the notches 16. The image sensor 20 is protruded above the carrier substrate 10. Thus, the diagonal dimension of the whole image sensing module 50 is equal to the diagonal dimension of the image sensor 20 or the diagonal dimension of the lens module 40, which is the minimum dimension the image sensing module 50 can achieve.

Refer to FIG. 13. In some embodiments, the signal transmission cables 51 may be bonded to the connection solder pads 13 (as shown in FIG. 2A) in a high temperature soldering methodology. After the cables 51 have been soldered to the carrier substrate 10, a protective resin material, such as a UV cured resin or a thermoset resin, is used to secure the connection points.

The abovementioned miniaturized image sensor packaging structure 100 is formed by the carrier substrate 10, a plurality of image sensors 20, the resin layer 30 and a plurality of lens modules 40. The miniaturized image sensor packaging structure 100 is cut to directly form a plurality of image sensing modules 50. In some embodiments, the miniaturized image sensor packaging structure 100 is formed by the carrier substrate 10, a plurality of image sensors 20 and the resin layer 30 (as shown in FIG. 5, FIG. 6A, and FIG. 6B). After cutting, the lens module 40 is fixed to the top of the image sensor 20. Thus is also obtained a single image sensing module 50.

The miniaturized image sensor packaging structure of the present invention can be used to generate an image sensing module, which contains a lens module and has a minimum size. The image sensing module may be used in various scenarios where very tiny objects are detected. The image sensor may be but is not limited to be an RGB image sensor, an infrared image sensor, a monochrome image sensor, or another niche-type image sensor.

In the miniaturized image sensor packaging structure and the image sensing module according to the embodiments of the present invention, both the image sensor and the lens module can be tested to verify the quality thereof before assemblage, whereby the present invention can overcome the conventional problem: the wafer-level packaging technology cannot screen out unqualified image sensors/lens modules but have to assemble them together no matter whether one or both of them are unqualified. Therefore, the present invention can increase the yield of assembling the image sensor and the lens module.

In the miniaturized image sensor packaging structure and the image sensing module according to the embodiments of the present invention, the image sensors and the lens modules are arranged on the carrier substrate in array and then joined together and packaged, whereby the present invention can realize a wafer-level-like production mode, achieve mass production, and realize miniaturization of image sensing modules and endoscopes.

In the miniaturized image sensor packaging structure and the image sensing module according to the embodiments of the present invention, the image sensors are fixed to the carrier substrate in a high-temperature reflow-soldering method, and then the lens modules are joined to the image sensors. Therefore, it is not necessary for the lens modules to use materials able to endure the high-temperature reflow-soldering process. Therefore, the present invention can increase the selectivity of materials, improve the flexibility and space of optical design, and lower the cost of lens modules.

In the miniaturized image sensor packaging structure and the image sensing module according to the embodiments of the present invention, the portions of the carrier substrate, which are corresponding to four corners of the image sensor, are perforated, whereby the diagonal dimension of the post-packaging and cutting carrier substrate is equal to or smaller than the diagonal dimension of the image sensing module. Thus, the maximum diagonal dimension of the image sensing module is equal to the larger one of the diagonal dimensions of the image sensor and the lens module. In other words, using the carrier substrate in packaging will not influence the final dimension of the image sensing module but may further decrease the diameter of the front end of the endoscope where the image sensing module is applied.

The front end of the endoscope is a circular structure. The minimum diameter of the front end of the endoscope is dependent on the diagonal dimension of the image sensing module. In other words, it is preferred: the diagonal dimension of the image sensor or image sensing module is as small as possible. In the embodiments mentioned above, the portions of the carrier substrate, which are corresponding to four corners of the image sensor, are removed to form through holes, whereby to achieve the minimum diagonal dimension of the image sensing module and miniaturize the front end of the endoscope.

In the miniaturized image sensor packaging structure and the image sensing module according to the embodiments of the present invention, the lenses, which are to be adhesively joined in the lens module, may be fabricated in a molding method or an injection-molding method. The fabrication cost of these lenses is much lower than the fabrication cost of the wafer-level lenses. The yield of fabricating these lenses is much higher than the yield of assembling the wafer-level lenses.

In the miniaturized image sensor packaging structure and the image sensing module according to the embodiments of the present invention, the image sensors and the lens modules, which are to be assembled, are KGD (Known Good Die) products that have been verified to function normally beforehand. Therefore, it is guaranteed: all the image sensors and the lens modules have been qualified before assemblage. Thus, the present invention can greatly increase the yield of the image sensing modules fabricated by mass assemblage.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the appended claims.

What is claimed is:

1. A miniaturized image sensor packaging structure, comprising
a carrier substrate, having a front surface and a back surface, wherein the front surface is divided into a plurality of package areas arranged in array; a plurality of solder pad-inner circuit sets is formed in each of the package areas and arranged in array; through holes are respectively formed in four corners of each of the package areas;
a plurality of image sensors, respectively disposed above the package areas, wherein four corners of each of the image sensors are respectively disposed above the through holes at the four corners of the carrier substrate and in a protruded state; and
a resin layer, formed between the image sensors and the carrier substrate.

2. The miniaturized image sensor packaging structure according to claim 1, wherein each of the solder pad-inner circuit sets includes a connection solder pad on the front surface of the carrier substrate; the image sensors are disposed above the front surface of the carrier substrate; each of the image sensors has a plurality of electrodes on a bottom thereof; the electrodes are electrically connected with the connection solder pads.

3. The miniaturized image sensor packaging structure according to claim 2, wherein each of the solder pad-inner circuit sets further includes an electrode solder pad on the back surface of the carrier substrate; the electrode solder pads are to be electrically connected with required electronic elements.

4. The miniaturized image sensor packaging structure according to claim 1, further comprising a plurality of lens modules, wherein the lens modules are respectively disposed on the image sensors; after the package areas have been separated by cutting, the carrier substrate, the image sensor, the resin layer and the lens module jointly form a single image sensing module.

5. The miniaturized image sensor packaging structure according to claim 4, wherein a diagonal dimension of the image sensing module is equal to a diagonal dimension of the image sensor or a diagonal dimension of the lens module.

6. The miniaturized image sensor packaging structure according to claim 4, wherein a combination of the image sensor and the lens module is in form of an image sensor containing lenses.

7. The miniaturized image sensor packaging structure according to claim 1, wherein the carrier substrate is a ceramic substrate, a printed circuit board (PCB) substrate, or a flexible printed circuit (FPC) substrate.

8. An image sensing module, comprising
a carrier substrate, having a front surface and a back surface, wherein a plurality of solder pad-inner circuit sets is formed on the front surface and arranged in array; four corners of the carrier substrate respectively have through holes;
an image sensor, disposed above the carrier substrate, wherein four corners of the image sensor are respectively disposed above the through holes at the four corners and in a protruded state;
a resin layer, formed between the image sensor and the carrier substrate; and
a lens module, disposed on the image sensor.

9. The mage sensing module according to claim 8, wherein each of the solder pad-inner circuit sets includes a connection solder pad on the front surface of the carrier substrate; the image sensor is disposed above the front surface of the carrier substrate; the image sensor has a plurality of electrodes on a bottom thereof; the electrodes are electrically connected with the connection solder pads.

10. The image sensing module according to claim 9, wherein each of the solder pad-inner circuit sets further includes an electrode solder pad on the back surface of the carrier substrate; the electrode solder pads are to be electrically connected with required electronic elements.

11. The image sensing module according to claim 8, wherein a combination of the image sensor and the lens module is in form of an image sensor containing lenses.

12. The image sensing module according to claim 8, wherein the carrier substrate is a ceramic substrate, a printed circuit board (PCB) substrate, or a flexible printed circuit (FPC) substrate.
